(19) United States
(12) Patent Application Publication
(10) Pub. No.: US 2002/0094692 A1
(43) Pub. Date: Jul. 18, 2002

(54) Method for carrying out a plasma etching process

(76) Inventor: Manfred Engelhardt, Feldkirchen-Westerham (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/969,178

(22) Filed: Oct. 2, 2001

Related U.S. Application Data
(63) Continuation of application No. PCT/DE01/00334, filed on Jan. 26, 2001.

(30) Foreign Application Priority Data
Feb. 2, 2000 (DE) 100 04 391.7

(51) Int. Cl. H01L 21/302; H01L 21/461

(52) U.S. Cl. 438/710

(57) ABSTRACT

A hard consumable mask is used which is consumed at a known rate during an etching process and is initially produced with a thickness such that the etching depth in the semiconductor material can be obtained as intended by comparing the etching rates of the material of the mask and of the semiconductor material to be etched.

### CROSS-REFERENCE TO RELATED APPLICATION

This application is a continuation of copending International Application No. PCT/DE01/00334, filed Jan. 26, 2001, which designated the United States.

### BACKGROUND OF THE INVENTION

FIELD OF THE INVENTION

The present invention relates to a method for carrying out a plasma etching process such that consumption of material can be monitored using a mask layer.

If semiconductor material is consumed by means of a plasma etching process during the production of semiconductor components on a semiconductor body or a semiconductor layer structure, it is necessary to identify the envisaged end point of the etching. This is because generally it is not permissible for the structures that are to be etched to be produced with an arbitrary etching depth. Rather, the etching process must be terminated at an envisaged location of the layer structure or when an envisaged etching depth is reached. It can happen that adequate optical end point identification via the plasma emission generated by the etching products is not possible. Furthermore, it can happen that a change in the consumption of optically emitting etching species (etchants used in the plasma) cannot be observed, in particular when the surface to be patterned by means of the etching on a semiconductor wafer is very small (e.g. when etching hole structures having a small diameter) and also when etching so-called recesses. During such instances of etching, the duration of the etching process is usually defined. Once the predetermined time has elapsed, taking account of a certain duration for the required overetch, the etching process is terminated. This means, however, that it is not possible to monitor the etching depth actually reached during the etching process.

### SUMMARY OF THE INVENTION

It is accordingly an object of the invention to provide a method for carrying out a plasma etching process with a monitorable etching depth which overcomes the above-mentioned disadvantageous of the prior art methods of this general type. In particular, it is an object of the present invention to provide such a method which can be carried out even without optically identifying the end point for the material to be patterned.

With the foregoing and other objects in view there is provided, in accordance with the invention, a method for carrying out a plasma etching process, which includes the following steps: providing a mask layer with openings; producing the mask layer from a material that will be consumed at a known rate in a desired plasma etching process; and producing the mask layer with a thickness such that at least regions of the mask layer will be completely consumed when a material to be etched is removed to an desired extent.

In accordance with an added feature of the invention, when performing the desired plasma etching process, an optical emission of the material of the mask layer is detected in a plasma and the detected optical emission is used to determine whether the material to be etched has been removed to the desired extent.

In accordance with an additional feature of the invention, when performing the desired plasma etching process, a change in a self-bias voltage that is characteristic of the plasma etching process is detected and the detected change in the self-bias voltage is used to determine whether the material to be etched has been removed to the desired extent.

In accordance with another feature of the invention, when performing the desired plasma etching process, an optical reflection of the mask layer is measured and the measured optical reflection is used to determine whether the material to be etched has been removed to the desired extent.

In the method according to the invention, a hard consumable mask is used for the plasma etching, which is completely consumed at least in regions during the etching process. Such a mask, which is applied to the surface to be etched, is produced from a material which is consumed at a known rate in the envisaged or desired plasma etching process. In this case, the thickness of the mask layer is chosen such that it is possible to predict how much of the semiconductor material that is actually to be etched away and whose etching rate is likewise known is consumed before the material of the mask is completely consumed, at least in regions. It suffices, therefore, to compare the etching rates of the material of the mask and of the semiconductor material to be consumed, in order to be able to determine the ratio of the required layer thickness of the mask layer to the etching depth in the semiconductor material. If the mask layer is applied to a required thickness, then the depth of the etching attack in the semiconductor material to be consumed can be determined very accurately by ascertaining when the mask layer is completely consumed, at least in regions. In this case, it is possible to take account of specific thickness fluctuations of the mask layer, which have the effect that, when using a virtually whole-area mask layer, the material of the mask is not completely consumed simultaneously at all points.

Other features which are considered as characteristic for the invention are set forth in the appended claims.

Although the invention is illustrated and described herein as embodied in a Method for carrying out a plasma etching process, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1 to 3 show cross sections of a top section of a semiconductor body 1, after different phases of a method for carrying out a plasma etching process.

### DESCRIPTION OF THE PREFERRED EMBODIMENTS

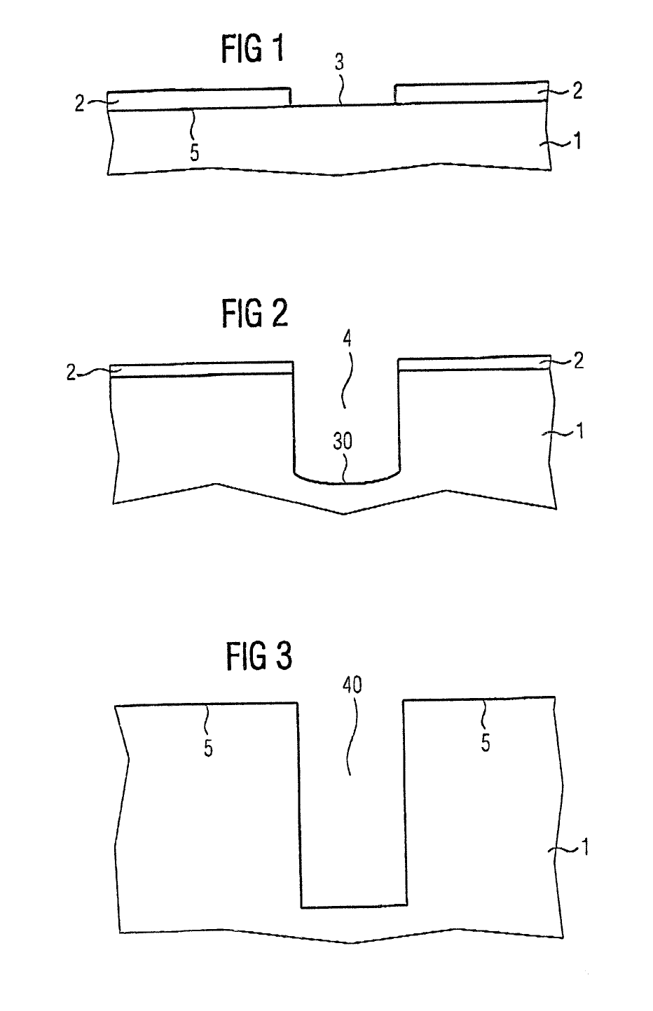

Referring now to the figures of the drawing in detail and first, particularly, to FIG. 1 thereof, there is shown a top side 5 of a semiconductor body 1. A mask 2 that has been dimensioned according to the invention is situated on the top side 5, which is to be etched. This mask 2 leaves free a region 3 of the surface of the top side 5, which is where the etchant is to attack.

FIG. 2 represents this detail in accordance with FIG. 1 after about half of the etching duration. The mask 2 now only has about half of its original thickness, while the material of the semiconductor body 1 has already been partly etched out in order to form a trench 4 or a hole or the like. Material of the semiconductor body 1 is consumed further from the bottom 30 of the trench.

FIG. 3 shows this cross section after the end of the etching process, with which, the desired trench 40 has been produced. The mask is now completely consumed, with the result that the top side 5 of the semiconductor body 1, which was covered by the mask, is now uncovered. In this case, the intention is not to preclude the situation in which individual island-like regions of the mask have still remained on the top side 5. What is essential to the method according to the invention, at any rate, is that the complete consumption of the mask can be ascertained, at least in regions. The depth of the trench 40 is determined by the selectivity of the etching of the semiconductor material of the semiconductor body 1 with regard to the material of the mask 2. The ratio of the etching depth in the semiconductor body 1 to the thickness of the mask layer is equal to the ratio of the etching rate in the semiconductor material to the etching rate in the material of the mask 2.

The end point of the etching can be detected in various ways. By way of example, it is possible to optically check the optical emission of the consumed material of the mask layer in the plasma. Moreover, during the etching, there is a change in the so-called self-bias voltage on the etched wafer, which voltage is characteristic of the plasma etching process. This change may be caused by a change in capacitance of the plasma over the wafer, which, in the plasma installation, represents an electrode to which a DC voltage is applied, or by a change in the impedance of the plasma. Moreover, it is possible directly to measure the optical reflection of the wafer surface, e.g. by means of laser interferometry, and thus to determine the extent to which the mask layer has already been removed from the surface of the wafer.

The method according to the invention therefore affords an expedient possibility for automatically identifying the end point of plasma etching processes. Such an end point identification by means of optical emission from the plasma is not possible using conventional methods.

I claim:

1. A method for carrying out a plasma etching process, which comprises:
providing a mask layer with openings;
producing the mask layer from a material that will be consumed at a known rate in a desired plasma etching process; and
producing the mask layer with a thickness such that at least regions of the mask layer will be completely consumed when a material to be etched is removed to an desired extent.

2. The method according to claim 1, which comprises: when performing the desired plasma etching process, detecting an optical emission of the material of the mask layer in a plasma and using the detected optical emission to determine whether the material to be etched has been removed to the desired extent.

3. The method according to claim 1, which comprises: when performing the desired plasma etching process, detecting a change in a self-bias voltage that is characteristic of the plasma etching process and using the detected change in the self-bias voltage to determine whether the material to be etched has been removed to the desired extent.

4. The method according to claim 1, which comprises: when performing the desired plasma etching process, measuring an optical reflection of the mask layer and using the measured optical reflection to determine whether the material to be etched has been removed to the desired extent.
